(19) United States
(12) Patent Application Publication
(10) Pub. No.: US 2026/0156908 A1
(43) Pub. Date: Jun. 4, 2026

(54) Stacked Semiconductor Device Including Thick Bottom Isolation Layer Below Gate Structure

(71) Applicant: SAMSUNG ELECTRONICS CO., LTD., Suwon-si (KR)

(72) Inventors: Junmo PARK, Clifton, NY (US); Jongmin SHIN, Schenectady, NY (US); Kang-ill SEO, Springfield, VA (US)

(73) Assignee: SAMSUNG ELECTRONICS CO., LTD., Suwon-si (KR)

(21) Appl. No.: 19/093,948

(22) Filed: Mar. 28, 2025

Related U.S. Application Data
(60) Provisional application No. 63/710,899, filed on Oct. 23, 2024.

(51) Int. Cl. H10D 84/01; H10D 64/23; H10D 84/83

(52) U.S. Cl. CPC H10D 84/0151; H10D 64/254; H10D 84/832

(57) ABSTRACT

Provided is a semiconductor device which includes: a channel structure; a source/drain region on the channel structure; a gate structure on the channel structure; and a bottom isolation layer below the gate structure and the source/drain region, wherein the bottom isolation layer is thicker vertically below the gate structure than vertically below the source/drain region.

### CROSS-REFERENCE TO RELATED APPLICATION

This application is based on and claims priority from U.S. Provisional Application No. 63/710,899 filed on Oct. 23, 2024 in the U.S. Patent and Trademark Office, the disclosure of which is incorporated herein in its entirety by reference.

### BACKGROUND

### 1. Field

Apparatuses and methods consistent with the disclosure relate to a stacked semiconductor device including a bottom isolation layer.

### 2. Description of Related Art

A stacked semiconductor device has been introduced in response to increased demand for an integrated circuit having high device density and performance. The stacked semiconductor device may include a 1^{st} transistor at a 1^{st} level and a 2^{nd} transistor at a 2^{nd} level vertically above the 1^{st} level, where each of the two transistors may be a fin field-effect transistor (FinFET), a nanosheet transistor, a forksheet transistor, or any other type of transistor.

The FinFET has one or more horizontally arranged vertical fin structures as a channel structure of which at least three surfaces are surrounded by a gate structure, and the nanosheet transistor is characterized by one or more nanosheet layers, which are vertically stacked or arranged on a substrate, as a channel structure and a gate structure surrounding all four surfaces of each of the nanosheet layers. The nanosheet transistor is referred to as gate-all-around (GAA) transistor, or as a multi-bridge channel field-effect transistor (MBCFET). The forksheet transistor is a combination of two nanosheet transistors with an isolation wall therebetween. Nanosheet layers of each nanosheet transistor are formed at each side of the isolation wall and pass through a gate structure in parallel with the isolation wall.

In addition to stacked semiconductor device, a backside power distribution network (BSPDN) for a semiconductor device has been introduced to address a heavy traffic of signal lines and power rails at a front side of the semiconductor device. The BSPDN may contribute to reducing contact resistance between circuit elements formed at the front side of the semiconductor device. Here, the front side refers to a side where a transistor is formed with respect to a top surface of a substrate, and the back side refers to a side opposite to the front side. The BSPDN is formed on a back side of a semiconductor device, and may include a backside metal line, such as a buried power rail, and a backside contact structure formed on a bottom surface of a source/drain region of a field-effect transistor such as a nanosheet transistor or a FinFET. The backside metal line may connect the backside contact structure to a voltage source or another circuit element for signal routing.

In the stacked semiconductor device, a bottom isolation layer of a bottom dielectric isolation (BDI) layer is formed to isolate a gate structure and a source/drain (S/D) region from the substrate or the backside isolation structure replacing at least a portion of the substrate therebelow, thereby preventing current leakage from the active structures of the stacked semiconductor device into the substrate and parasitic capacitance therefrom.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides a semiconductor device in which a bottom isolation layer formed on a base layer such as a silicon-based substrate or a backside isolation structure has different thicknesses below a gate structure and below a source/drain region so that isolation performance may be improved between the gate structure and a backside contact structure formed on the source/drain region and a volume of an epitaxial structure for the source/drain region is increase to improve device performance.

According to an aspect of the disclosure, there is provided a semiconductor device which may include: a channel structure; a source/drain region on the channel structure; a gate structure on the channel structure; and a bottom isolation layer below the gate structure and the source/drain region, wherein the bottom isolation layer is thicker vertically below the gate structure than vertically below the source/drain region.

According to an aspect of the disclosure, there is provided a semiconductor device which may include: a base layer including silicon or a dielectric material; a channel structure on the base layer; a 1^{st} source/drain region on the channel structure; a gate structure on the channel structure; and a bottom isolation layer having different thicknesses along a channel-length direction on the base layer and vertically below the channel structure, the gate structure and the 1^{st} source/drain region.

According to an aspect of the disclosure, there is provided a method of manufacturing a semiconductor device, which may include: forming a base layer; forming a channel structure on the base layer; forming a 1^{st} source/drain region on the channel structure; forming a gate structure on the channel structure; and forming a bottom isolation layer having different thicknesses along a channel-length direction on the base layer below the channel structure, the gate structure and the 1^{st} source/drain region.

### BRIEF DESCRIPTION OF DRAWINGS

Example embodiments of the disclosure will be more clearly understood from the following detailed description taken in conjunction with the accompanying drawings.

FIGS. 1 and 2A-2C illustrate a stacked semiconductor device including a bottom isolation layer, according to one or more embodiments.

FIGS. 3A-3C illustrate a stacked semiconductor device in which a bottom isolation layer has different thicknesses below a gate structure and below a source/drain region, according to one or more embodiments.

FIG. 4A illustrates a stacked semiconductor device in which a backside isolation structure is formed to replace a silicon-based substrate and a bottom isolation layer is formed on the backside isolation structure to have different thicknesses below a gate structure and below a source/drain region, according to one or more embodiments.

FIG. 4B illustrates a stacked semiconductor device including inner spacers and a bottom isolation layer having different thicknesses below a gate structure and below a source/drain region, according to one or more embodiments.

FIG. 4C illustrates a stacked semiconductor device including inner spacers in which a backside isolation structure is formed to replace a silicon-based substrate and a bottom isolation layer is formed on the backside isolation structure to have different thicknesses below a gate structure and below a source/drain region, according to one or more embodiments.

FIGS. 5A-5K illustrate cross-section views of intermediate semiconductor devices after respective steps of manufacturing a stacked semiconductor device in which a bottom isolation layer has different thicknesses below a gate structure and below a source/drain region, according to one or more embodiments.

FIGS. 6A and 6B illustrate a flowchart of a method of manufacturing a stacked semiconductor device in which a bottom isolation layer has different thicknesses below a gate structure and below a source/drain region, according to one or more other embodiments.

FIG. 7 is a schematic block diagram illustrating an electronic device including a stacked semiconductor device in which a bottom isolation layer has different thicknesses below a gate structure and below a source/drain region, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures.

For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, elements referred to as a “left” element and a “right” element” may be a “right” element and a “left” element when a device or structure including these elements are differently oriented. Thus, herein, a “left” element and a “right” element of a structure may also be referred to as a “1^{st}” element and a “2^{nd}” element, respectively, of the structure as long as their structural relationship is clearly understood in the context of the descriptions.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2nd element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

In the descriptions herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain region, a silicide layer such as cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” pertains to electrical insulation or separation between structures, layers, components or regions in a corresponding device or structure.

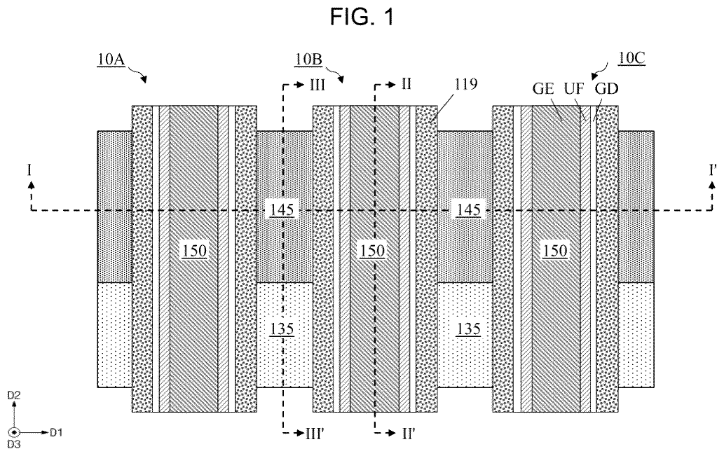

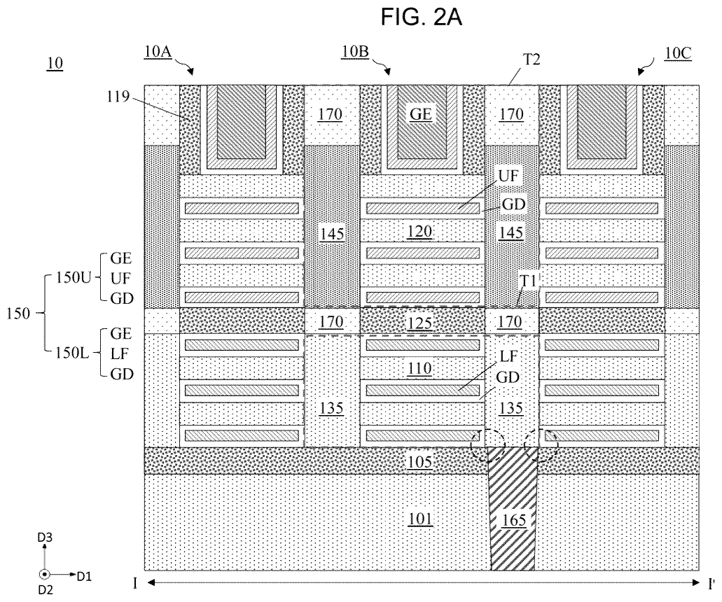

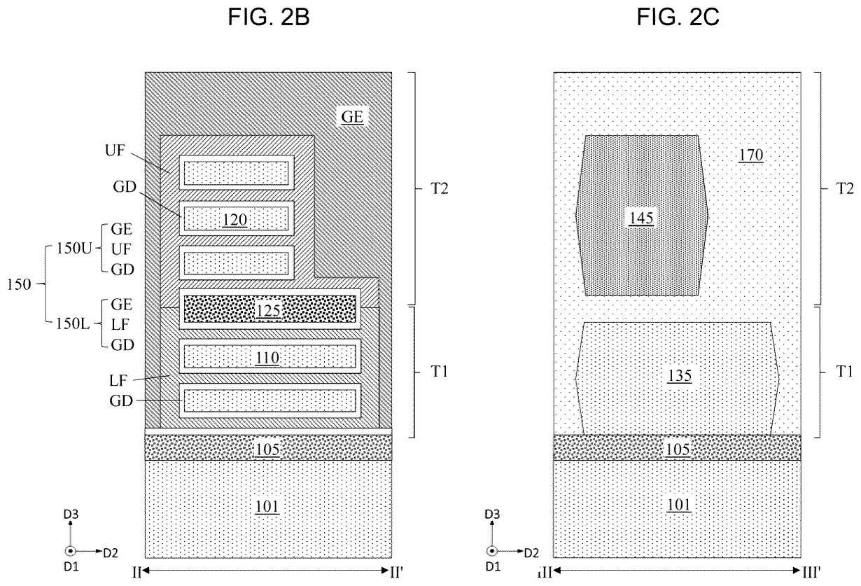

FIGS. 1 and 2A-2C illustrate a stacked semiconductor device including a bottom isolation layer, according to one or more embodiments.

FIG. 1 is a plan view of a stacked semiconductor device 10 and FIGS. 2A-2C are cross-section views of the stacked semiconductor device 10 shown in FIG. 1 taken along lines I-I′, II-II′ and III-III′, respectively. It is to be understood here that FIG. 1 is provided to show a positional relationship between gate structures and source/drain regions, and thus, some structural elements such as an interlayer isolation structure, contact structures, etc. shown in FIGS. 2A-2C are omitted in FIG. 1 for brevity purposes.

As shown in FIG. 1, a 1^{st} direction D1 is a channel-length direction in which current flows between two source/drain regions connected to each other through a channel structure, a 2^{nd} direction D2 is a channel-width direction or a cell-height direction that horizontally intersects the 1^{st} direction D1, and a 3^{rd} direction D3 is a channel-thickness direction that vertically intersects the 1^{st} direction D1 and the 2^{nd} direction D2. The 1^{st} direction D1 and the 2^{nd} direction D2 are referred to as horizontal directions, and the 3^{rd} direction D3 is referred to as a vertical direction.

Referring to FIGS. 1 and 2A-2C, the stacked semiconductor device 10 may include a 1^{st} channel stack 10A, a 2^{nd} channel stack 10B and a 3^{rd} channel stack 10C, each of which includes a 1^{st} channel structure formed of a plurality of 1^{st} channel layers 110 and a 2^{nd} channel structure formed of a plurality of 2^{nd} channel layers 120 vertically above the 1^{st} channel structure. The 1^{st} channel structure may be formed at a 1^{st} level on a base layer 101, and the 2^{nd} channel structure may be formed at a 2^{nd} level above the 1^{st} level. These channel layers 110 and 120 may be epitaxially grown from the base layer 101 which may be a silicon-based substrate. Between the two channel structures may be formed a middle isolation layer 125 which isolates the two channel structures from each other. Further, a bottom isolation layer 105 may be formed on a top surface of the base layer 101 to extend in the 1^{st} direction D1 to isolate the base layer 101 from active structures of the stacked semiconductor device 10 including the channel stacks 10A-10C. The bottom isolation layer 105 will be described later in detail.

The 1^{st} channel layers 110 may connect 1^{st} source/drain regions 135 at both sides thereof to each other so that current can flow therebetween at a control of a 1^{st} gate structure 150L which surrounds the 1^{st} channel layers 110. Similarly, the 2^{nd} channel layers 120 may connect 2^{nd} source/drain regions 145 at both sides thereof to each other so that current can flow therebetween at a control of a 2^{nd} gate structure 150U which surrounds the 2^{nd} channel layers 120. The 1^{st} gate structure 150L and the 2^{nd} gate structure 150U form a gate structure 150 of the stacked semiconductor device 10. The 1^{st} source/drain regions 135 may be epitaxially grown from the 1^{st} channel layers 110 of the 1^{st} channel structure in the channel stacks 10A-10C, and the 2^{nd} source/drain regions 145 may be epitaxially grown from the 2^{nd} channel layers 120 of the 2^{nd} channel structure in the channel stacks 10A-10C. The gate structure 150 may be formed by replacing a dummy gate structure and a plurality of sacrificial layers in a process of manufacturing the stacked semiconductor device 10.

Thus, in the stacked semiconductor device 10, the 1^{st} channel layers 110 along with the 1^{st} source/drain regions 135 at both sides thereof and the 1^{st} gate structure 150L surrounding these 1^{st} channel layers 110 may form a 1^{st} transistor T1, which is a nanosheet transistor, at the 1^{st} level. Further, the 2^{nd} channel layers 120 along with the 2^{nd} source/drain regions 145 at both sides thereof and the 2^{nd} gate structure 150U surrounding these 2^{nd} channel layers 120 may form a 2^{nd} transistor T2, which is also a nanosheet transistor, at the 2^{nd} level.

The base layer 101 may be formed of silicon (Si). Additionally, or alternatively, it may include other materials such as silicon germanium (SiGe), silicon carbide (SiC), not being limited thereto. The 1^{st} channel layers 110 and the 2^{nd} channel layers 120 may each be formed of silicon (Si) or silicon germanium (SiGe). The 1^{st} source/drain regions 135 and the 2^{nd} source/drain regions 145 may also be formed of Si or SiGe. However, when the 1^{st} source/drain regions 135 are formed of Si and doped with n-type impurities such as phosphorus (P), arsenic (As), antimony (Sb), etc., the 1^{st} transistor T1 may form an n-type transistor. In contrast, when the 2^{nd} source/drain regions 145 are formed of SiGe and doped with p-type impurities such as boron (B), gallium (Ga), indium (In), etc., the 2^{nd} transistor T2 may form a p-type transistor.

However, the disclosure is not limited thereto. Each of the 1^{st} transistor T1 and the 2^{nd} transistor T2 may be either p-type or n-type, according to one or more other embodiments.

The 1^{st} gate structure 150L of the 1^{st} transistor T1 may include a gate dielectric layer GD, a 1^{st} work-function metal layer LF and a gate electrode GE, and the 2^{nd} gate structure 150U may include the gate dielectric layer GD, a 2^{nd} work-function metal layer UF and the gate electrode GE.

The gate dielectric layer GD may include an interfacial layer and a high-k dielectric layer formed on the interfacial layer. The interfacial layer may be formed on each of the channel layers 110 and 120 to protect the channel layers 110 and 120 and facilitate growth of the high-k dielectric layer thereon, and the high-k dielectric layer may be formed on the interfacial layer to allow an increased gate capacitance without associated current leakage from the gate structure 150. For these purposes, the interfacial layer may be formed of an oxide material such as silicon oxide (SiO or SiO₂) and/or silicon oxynitride (SiON), not being limited thereto, and the high-k dielectric layer may be formed of a high-k material such as hafnium oxide (HfO₂), hafnium silicate (HfSiO₄), titanium oxide (TiO₂), zirconium oxide (ZrO₂), aluminum oxide (Al₂O₃), lanthanum oxide (La₂O₃), yttrium oxide (Y₂O₃), etc.

The 1^{st} work-function metal layer LF may formed on the gate dielectric layer GD surrounding the 1^{st} channel layers 110 to control a gate threshold voltage for the 1^{st} transistor T1, and the 2^{nd} work-function metal layer UF may formed on the gate dielectric layer GD surrounding the 2^{nd} channel layers 120 to control a gate threshold voltage for the 2^{nd} transistor T2. Each of the work-function metal layers LF and UF may be formed of metal such as Ti, Ta, Al, W, TiN, WN, TiAl, TiAlN, TaN, TiC, TaC, TiAIC, TaCN, TaSiN, and/or a combination thereof, not being limited thereto. However, the 1^{st} work-function metal layer LF for the 1^{st} transistor T1 and the 2^{nd} work-function metal layer UF for the 2^{nd} transistor T2 may be formed of different materials when the two transistors are of different polarity types, i.e., n-type and p-type, respectively. For example, when the 1^{st} transistor T1 is of n-type and the 2^{nd} transistor T2 is of p-type, the 1^{st} work-function metal layer LF may be formed of Al or TiC, and the 2^{nd} work-function metal layer UF may be formed of TiN.

The 1^{st} work-function metal layer LF may be isolated from the 1^{st} source/drain regions 135 by the gate dielectric layer GD, and the 2^{nd} work-function metal layer UF may be isolated from the 2^{nd} source/drain regions 145 also by the gate dielectric layer GD.

Although the two transistors T1 and T2 have different work-function metal layers LF and UF, respectively, the same gate electrode GE may surround the two work-function metal layers LF and UF to form the two transistors T1 and T2 as a complementary metal-oxide-semiconductor (CMOS) device, e.g., an inverter circuit. The gate electrode GE may be formed of a metal such as Cu, W, Al, Ru, Mo, Co, etc., or a metal alloy thereof. However, the disclosure is not limited thereto, and a gate isolation layer or structure may be formed to separate the gate structure 150 into two gate structures for the respective two transistors T1 and T2. For example, a gate electrode on the 1^{st} work-function metal layer LF may be isolated from a gate electrode on the 2^{nd} work-function metal layer UF.

An interlayer isolation structure 170 may be formed to surround the source/drain regions 135 and 145 to isolate these semiconductor structures from each other and other circuit elements. The interlayer isolation structure 170 may be formed of a low-k dielectric material such as silicon oxide (e.g., SiO₂).

Gate spacers 119 may be respectively formed on a left side surface and a right side surface of an upper portion of the gate structure 150 disposed above the uppermost 2^{nd} channel layer 120 in each of the channel stacks 10A-10C. For example, the gate spacers 119 may be respectively formed on a left side surface and a right side surface of the gate dielectric layer included in the upper portion of the gate structure 150 in each of the channel stacks 10A-10C. Thus, the gate spacers 119 may also laterally face the 2^{nd} source/drain regions 145 and/or a portion of the interlayer isolation structure 170 formed vertically above the 2^{nd} source/drain regions 145.

The gate spacers 119 may be used to protect a dummy gate structure formed of polycrystalline silicon (p-Si) or amorphous silicon (a-Si) from various processes performed in manufacturing the 3D-stacked semiconductor device 10, and remain after the dummy gate structure is replaced by the gate structure 150 to prevent current leakage therefrom to other circuit elements. The gate spacer 119 may be formed of silicon nitride (e.g., SiN or Si₃N₄), SiBCN, SiCN, SiOC, SiOCN, silicon oxide (e.g., SiO₂), etc., not being limited thereto.

As shown in FIGS. 1 and 2B, the 2^{nd} channel structure formed of the 2nd channel layers 120 may have a smaller width in the 2^{nd} direction D2 than the 1^{st} channel structure formed of the 1^{st} channel layers 110, and the 2^{nd} channel layers 120 may only partially overlap the 1^{st} channel layer 110 in the 3^{rd} direction D3. For example, left side surfaces of the channel layers 110 and 120 may be aligned or coplanar with each other in the 3^{rd} direction D3, while right side surfaces thereof are not. Thus, as shown in FIG. 2C, the 2^{nd} source/drain regions 145 epitaxially grown from the 2^{nd} channel layers 120 may also be formed to have a smaller width in the 2^{nd} direction D2 than the 1^{st} source/drain regions 135 epitaxially grown from the 1^{st} channel layers 110, and a right portion of the 1^{st} source/drain region 135 may not be overlapped by the 2^{nd} source/drain region 145 in the 3^{rd} direction D3. This width difference of the source/drain regions provides a free space above a top surface of each of the 1^{st} source/drain regions 135 which is not vertically overlapped by the 2^{nd} source/drain region 145 so that other circuit elements such as a source/drain contact structure may be formed through this space to contact at least a portion of the top surface of the 1^{st} source/drain region 135. The foregoing characteristics of the channel structures and the source/drain regions may be provided to address increasing demands for a high device density in a semiconductor device including the stacked semiconductor device 10.

The 2^{nd} channel structure forming the 2^{nd} transistor T2 may have a greater number of channel layers than that of the 1^{st} channel structure forming the 1^{st} transistor T1 such that the two transistors may have the same or substantially same effective channel width (Weff). For example, the 2^{nd} channel structure may have three channel layers while the 1^{st} channel structure have two channel layers as shown in FIGS. 2A and 2B.

The different channel widths and the different number of channel layers may facilitate optimization of a stacked semiconductor device in terms of not only an area gain for a high-density semiconductor device but also device performance such as current speed, work load distribution, power efficiency, contact resistance, thermal control, structural stability, etc.

The stacked semiconductor device may also include a backside contact structure 165 formed on a bottom surface of one of the 1^{st} source/drain regions 135. The backside contact structure 165 may connect the 1^{st} source/drain region 135 to a voltage source or another circuit element for signal routing. The backside contact structure 165 may each be formed of a metal or metal alloy including at least one of Cu, W, Al, Ru, Mo, Co, etc.

The backside contact structure 165 may be formed through the bottom isolation layer 105 to be connected to the bottom surface of the 1^{st} source/drain region 135. The bottom isolation layer 105 may be formed of a material such as silicon nitride (e.g., SiN or Si₃N₄), SiBCN, SiCN, SiOC, SiOCN, silicon oxide (e.g., SiO₂), etc., not being limited thereto. The middle isolation layer 125 may be formed of the same material forming the bottom isolation layer 105. However, an upper-left edge and an upper-right edge of the backside contact structure 165 (dashed-circle portions in FIG. 2A) may be disposed very close to the respective gate structures 150 in the channel stacks 10B and 10C. For example, even if the gate dielectric layer is formed the 1^{st} work-function metal layer LF of the 1^{st} gate structure 150L in the 2^{nd} channel stack 10B may have a short-circuit risk with respect to the backside contact structure 165. Further, the bottom isolation layer 105 may prevent sufficient growth of the 1^{st} source/drain region 135 in the process of manufacturing the stacked semiconductor device 10, and thus, performance improvement of the stacked semiconductor device 10 by increasing a volume of the 1^{st} source/drain region 135 may be limited by the bottom isolation layer 105.

Thus, the following embodiments may address the above-described issues of the bottom isolation layer 105.

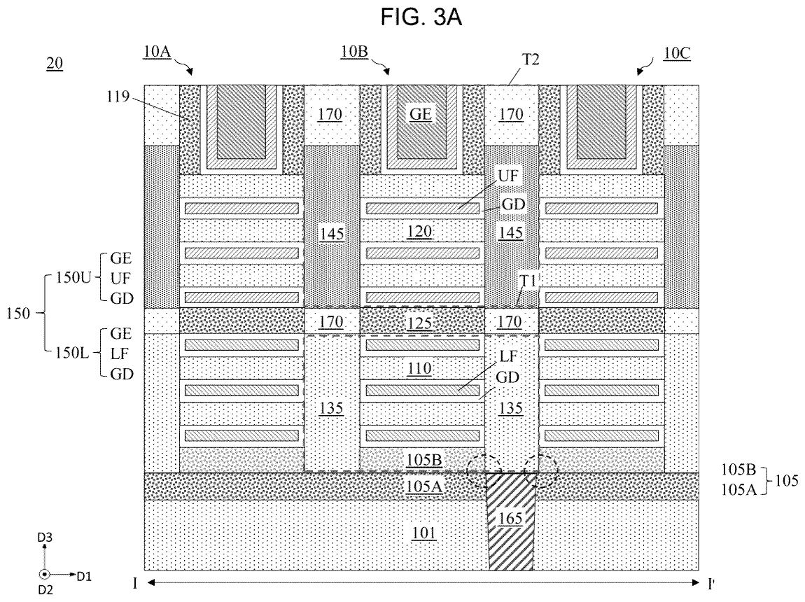

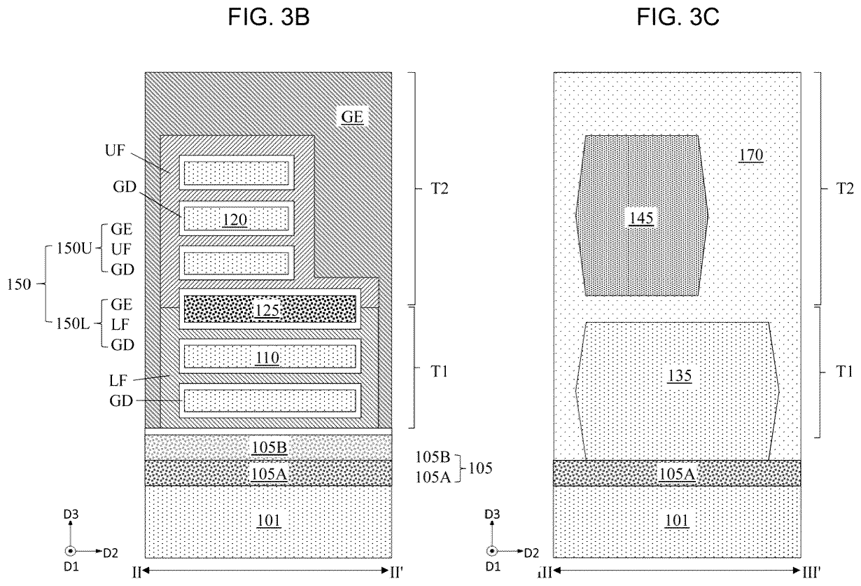

FIGS. 3A-3C illustrate a stacked semiconductor device in which a bottom isolation layer has different thicknesses below a gate structure and below a source/drain region, according to one or more embodiments.

Referring to FIGS. 3A-3C, a stacked semiconductor device 20 may include the same structural elements forming the stacked semiconductor device 10 of FIGS. 2A-2C including the backside contact structure 165 and the bottom isolation layer 105. Thus, the duplicate descriptions thereof may be omitted herein.

However, the stacked semiconductor device 20 differs from the stacked semiconductor device 10 in that the bottom isolation layer 105 vertically below each of the channel structures 10A-10C including the gate structure 150 may be formed to be thicker than below the 1^{st} source/drain region 135. For example, the bottom isolation layer 105 may include a 1^{st} bottom isolation layer 105A and a 2^{nd} bottom isolation layer 105B below the gate structure 150 while only the 1^{st} bottom isolation layer 105A may be formed below the 1^{st} source/drain region 135. Thus, a bottom surface of the 1^{st} source/drain region 135, on which the backside contact structure 165 is not formed, may contact a top surface of the 1^{st} bottom isolation layer 105A and a lower side surface of this 1^{st} source/drain region 135 may contact a side surface of the 2^{nd} bottom isolation layer 105B. Thus, in the stacked semiconductor device 20, the bottom isolation layer 105 may have different thicknesses along a channel-length direction on the base layer 101 vertically below the 1^{st} source/drain regions, the 1^{st} channel structure, and the 1^{st} gate structure 150L.

Due to the above-described structure, the distance between each of the upper-left edge and the upper-right edge of the backside contact structure 165 (dashed-circle portions in FIG. 3A) and the gate structure 150 may have a sufficient margin to prevent or reduce a short-circuit risk therebetween. For example, a top surface of the backside contact structure 165 contacting the 1^{st} source/drain region 135 may be at a level below the bottommost surface of the gate structure 150, that is, a bottom surface of the gate dielectric layer GD on the lowermost 1^{st} channel layer 110.

Further, due to the 2^{nd} bottom isolation layer 105B, the 1^{st} source/drain region 135 of the stacked semiconductor device 20 may be formed to be thicker than the 1^{st} source/drain region 135 of the stacked semiconductor device 10 by at least a thickness of the 2^{nd} bottom isolation layer 105B in the 3^{rd} direction D3. Thus, performance improvement of the stacked semiconductor device 20 by increasing a volume of the 1^{st} source/drain region 135 may be achieved, compared to the stacked semiconductor device 10 shown in FIGS. 2A-2C.

In the above embodiments of FIGS. 2A-2C and 3A-3C, each of the channel stacks 10A-10C may be formed on the base layer 101 which may be a silicon-based substrate, and the backside contact structure 165 may be formed in this substrate with the bottom sacrificial layer 105 thereon. However, the base layer 101 may be a backside isolation structure formed of a low-k material such as silicon oxide (e.g., SiO₂), which has replaced an original substrate formed of silicon.

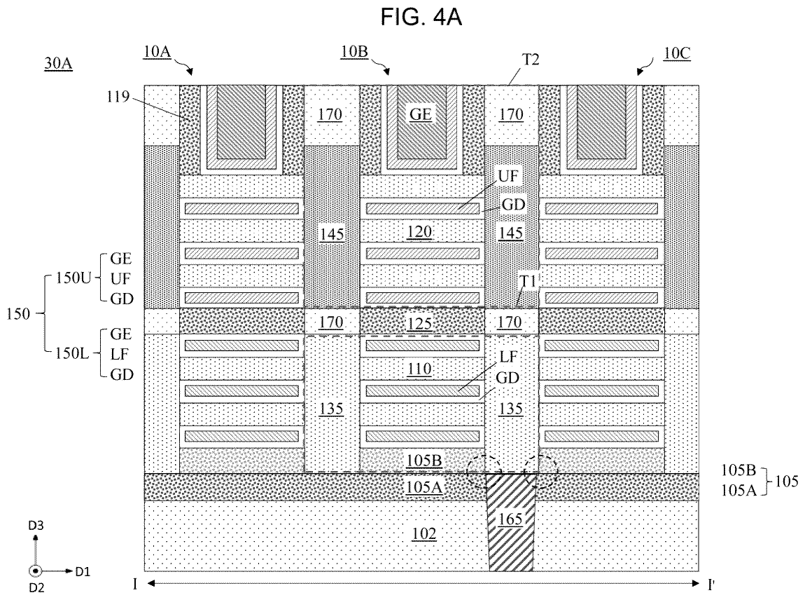

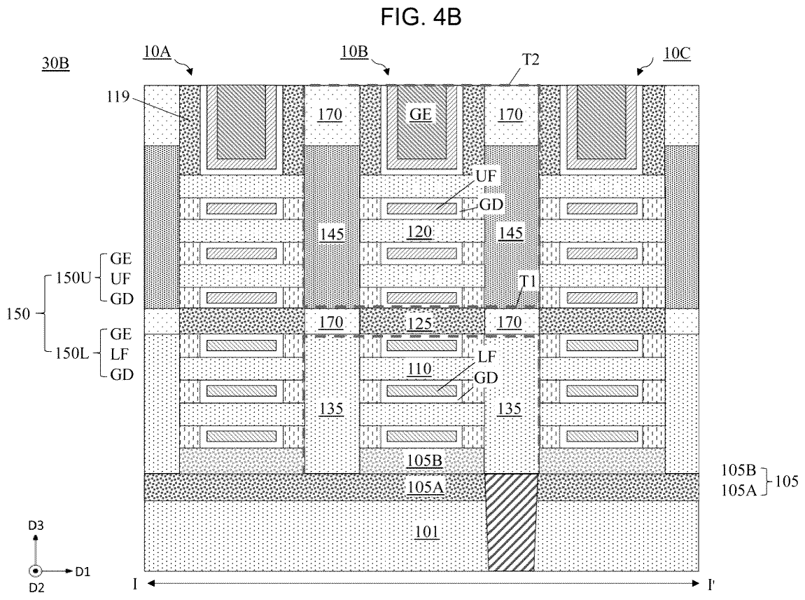

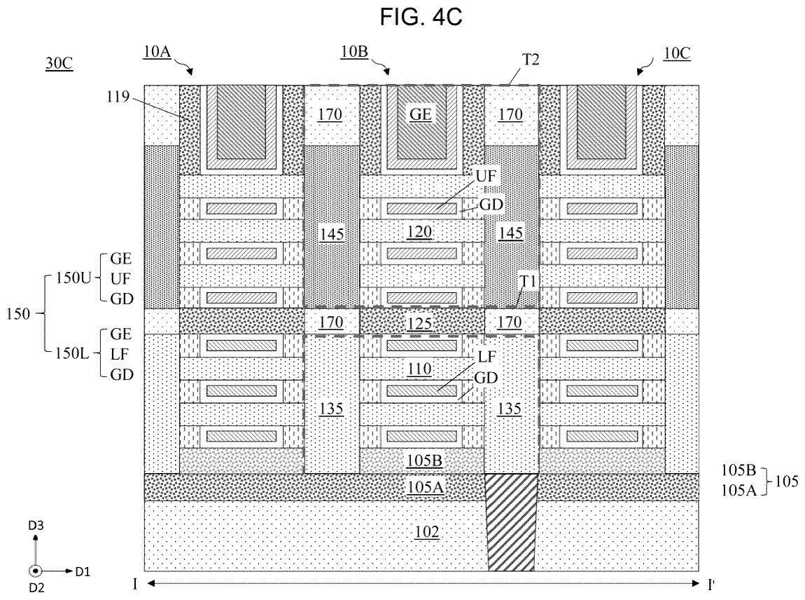

FIG. 4A illustrates a stacked semiconductor device in which a backside isolation structure is formed to replace a silicon-based substrate and a bottom isolation layer is formed on the backside isolation structure to have different thicknesses below a gate structure and below a source/drain region, according to one or more embodiments.

Referring to FIG. 4A, a stacked semiconductor device 30A may include the same structural elements forming the stacked semiconductor device 20 of FIGS. 3A-3C including the bottom isolation layer 105 formed of the 1^{st} bottom isolation layer 105A and the 2^{nd} bottom isolation layer 105B. Thus, the duplicate descriptions thereof may be omitted herein. However, the stacked semiconductor device 30A differs from the stacked semiconductor device 20 in that each of the channel stacks 10A-10C including the 2^{nd} bottom isolation layer 105B is formed on a base layer 102, which may be a backside isolation structure, with the 1^{st} bottom isolation layer 105A thereon. Thus, the backside contact structure 165 may be formed to penetrate through the 1^{st} bottom isolation layer 105A into the backside isolation structure.

The backside isolation structure as the base layer 102 may be formed of a low-k material such as silicon oxide (e.g., SiO₂). The backside isolation structure may be formed through a backside process which removes and replaces at least a portion of an original silicon-based substrate such as the base layer 101 of the stacked semiconductor device 20. By forming the backside isolation structure instead of the at least a portion of the silicon-based substrate in the stacked semiconductor device 30A, a parasitic capacitance between the substrate and the backside contact structure 165 formed of a metal or a metal alloy may be reduced and isolation performance may increase. Still, however, the stacked semiconductor device 30A may include the bottom isolation layer 105 having different thicknesses below the gate structure 150 and below the 1^{st} source/drain region 135 to improve device performance as described above.

In the above embodiments of FIGS. 2A-2C, 3A-3C and 4A, the gate dielectric layer GD is formed as an isolation structure between the 1^{st} source/drain region 135 and the 1^{st} work-function metal layer LF and between the 2^{nd} source/drain region 145 and the 2^{nd} work-function metal layer UF. However, for this isolation purpose, inner spacers may be formed in the stacked semiconductor device

FIG. 4B illustrates a stacked semiconductor device including inner spacers and a bottom isolation layer having different thicknesses below a gate structure and below a source/drain region, according to one or more embodiments.

Referring to FIG. 4B, a stacked semiconductor device 30B may include the same structural elements forming the stacked semiconductor device 10 of FIGS. 3A-3C including the bottom isolation layer 105 formed of the 1^{st} bottom isolation layer 105A and the 2^{nd} bottom isolation layer 105B. Thus, the duplicate descriptions thereof may be omitted herein. However, the stacked semiconductor device 30B differs from the stacked semiconductor device 20 in that inner spacers 103 may be formed between the 1^{st} source/drain region 135 and the 1^{st} work-function metal layer LF and between the 2^{nd} source/drain region 145 and the 2^{nd} work-function metal layer UF to isolate these structural elements. The inner spacers 103 may be formed of silicon nitride (e.g., SiN or Si₃N₄), not being limited thereto. Still, however, the stacked semiconductor device 30B may include the bottom isolation layer 105 having different thicknesses below the gate structure 150 and below the 1^{st} source/drain region 135 to improve device performance as described above.

In the meantime, the substrate 101 of the stacked semiconductor device 30B including the inner spacers 103 may also be replaced by a backside isolation structure as in the stacked semiconductor device 30A as shown in FIG. 4C.

FIG. 4C illustrates a stacked semiconductor device including inner spacers in which a backside isolation structure is formed to replace a silicon-based substrate and a bottom isolation layer is formed on the backside isolation structure to have different thicknesses below a gate structure and below a source/drain region, according to one or more embodiments.

Referring to FIG. 4C, a stacked semiconductor device 30C may include the same structural elements forming the stacked semiconductor device 30B of FIG. 4B including the bottom isolation layer 105 formed of the 1^{st} bottom isolation layer 105A and the 2^{nd} bottom isolation layer 105B. Thus, the duplicate descriptions thereof may be omitted herein. However, the stacked semiconductor device 30C differs from the stacked semiconductor device 30B in that each of the channel stacks 10A-10C including the 2^{nd} bottom isolation layer 105B is formed on a base layer 102, which may be a backside isolation structure, with the 1^{st} bottom isolation layer 105A thereon. Thus, the backside contact structure 165 may be formed to penetrate through the 1^{st} bottom isolation layer 105A into the backside isolation structure.

The backside isolation structure as the base layer 102 may be formed of a low-k material such as silicon oxide (e.g., SiO₂). The backside isolation structure may be formed through a backside process which removes and replaces at least a portion of an original silicon-based substrate such as the base layer 101 of the stacked semiconductor device 20. By forming the backside isolation structure instead of the at least a portion of the silicon-based substrate in the stacked semiconductor device 30A, a parasitic capacitance between the substrate and the backside contact structure 165 formed of a metal or a metal alloy may be reduced and isolation performance may increase. Still, however, the stacked semiconductor device 30C may include the bottom isolation layer 105 having different thicknesses below the gate structure 150 and below the 1^{st} source/drain region 135 to improve device performance as described above.

Herebelow, a method of manufacturing a stacked semiconductor device corresponding to the stacked semiconductor device 20 of FIGS. 3A-3C is provided.

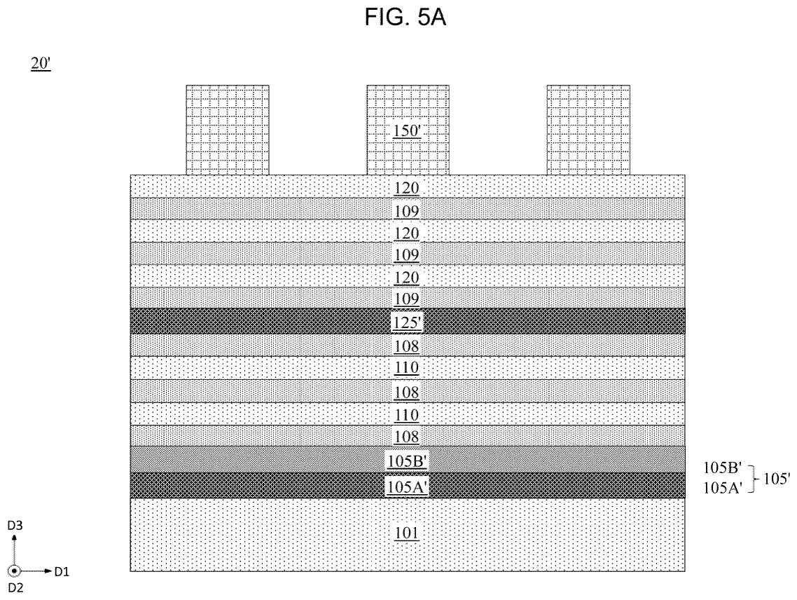

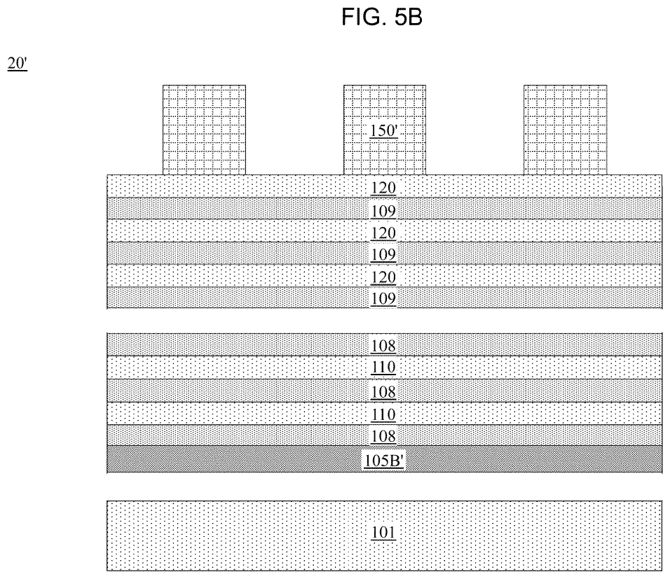

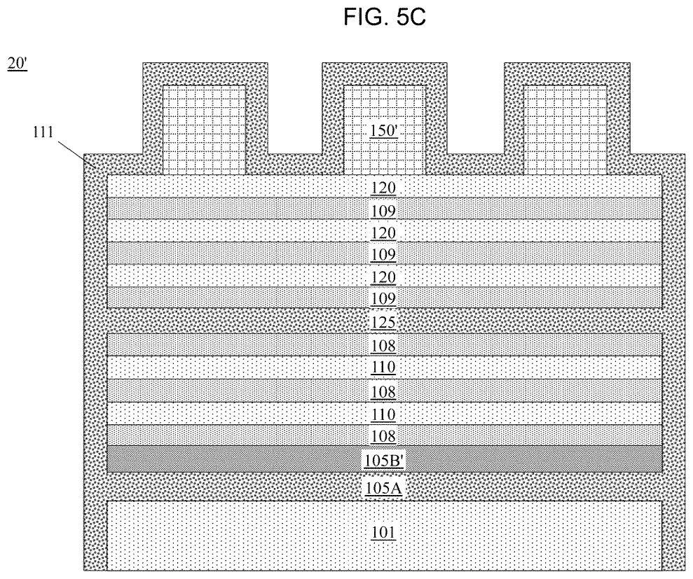

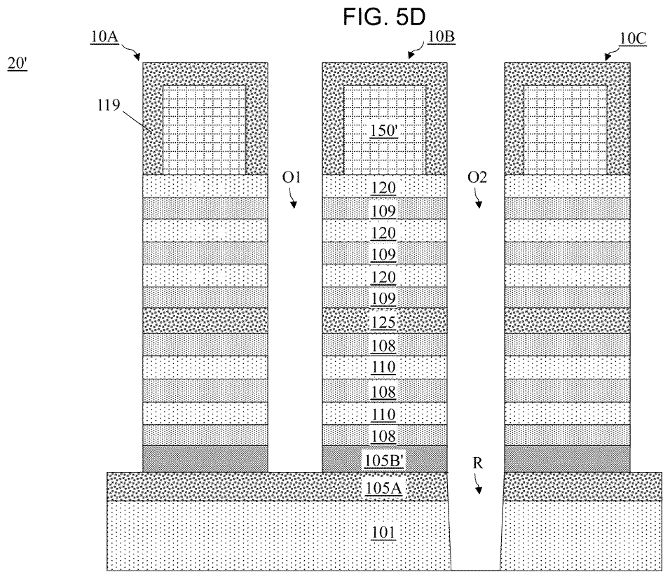

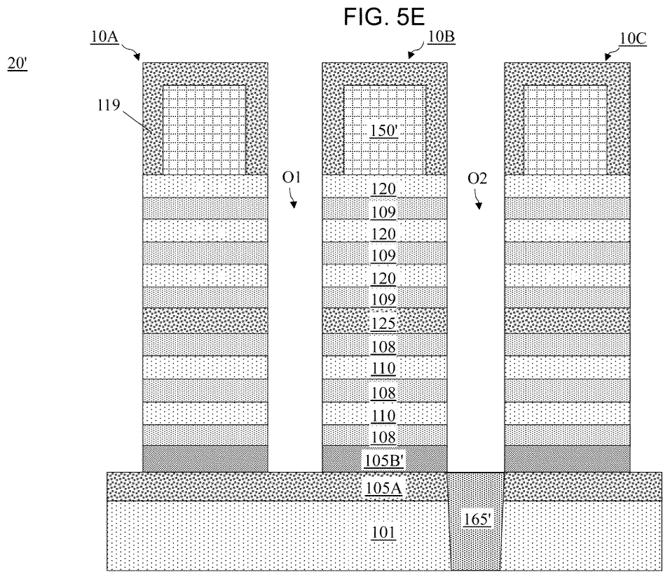

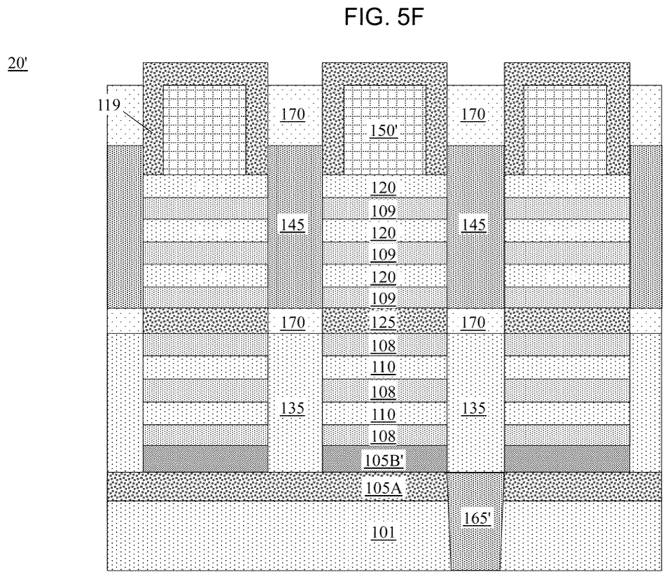

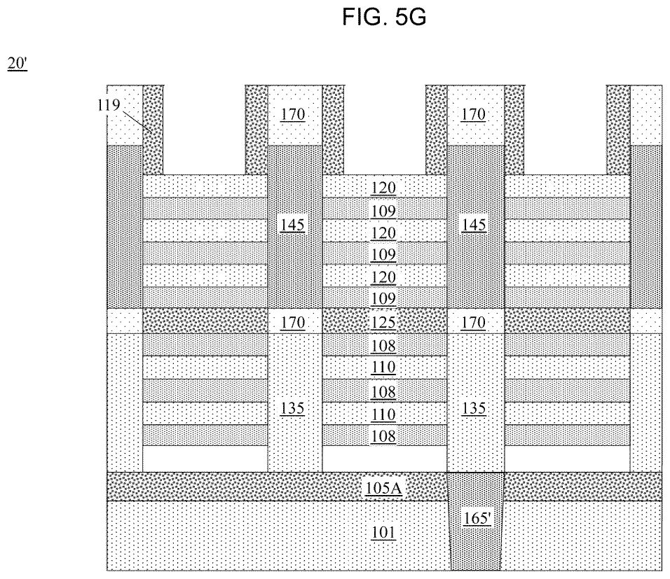

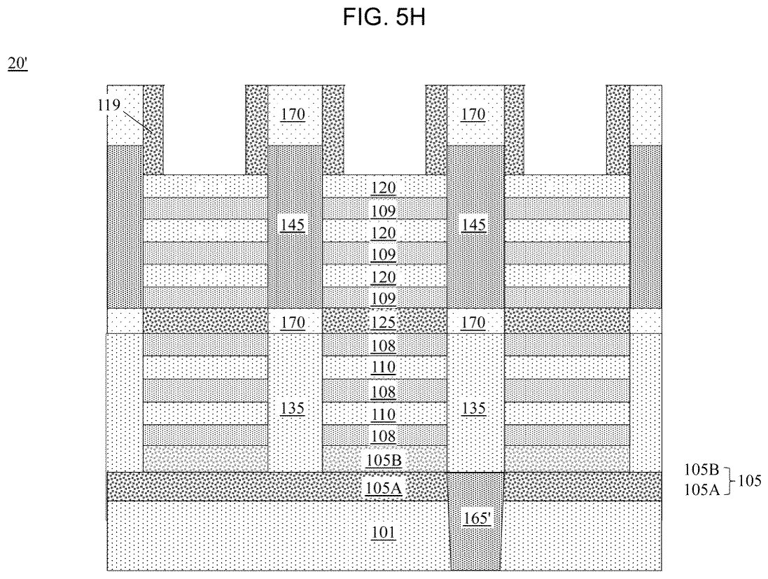

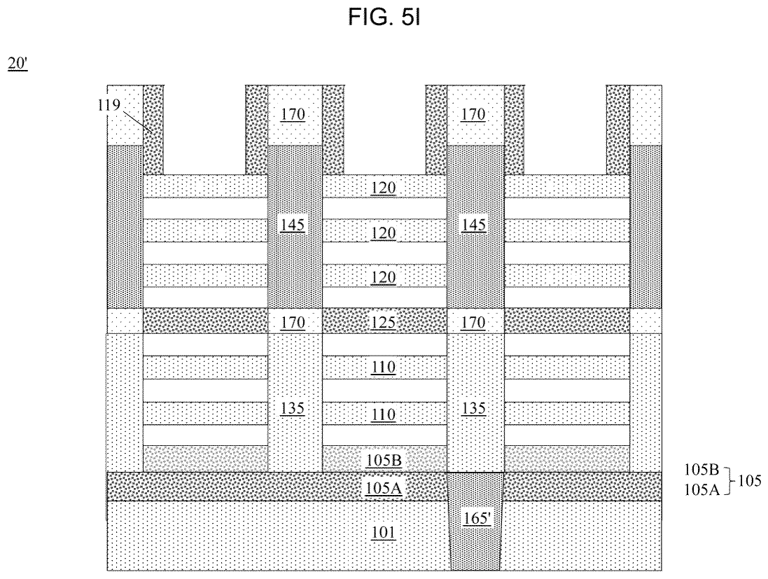

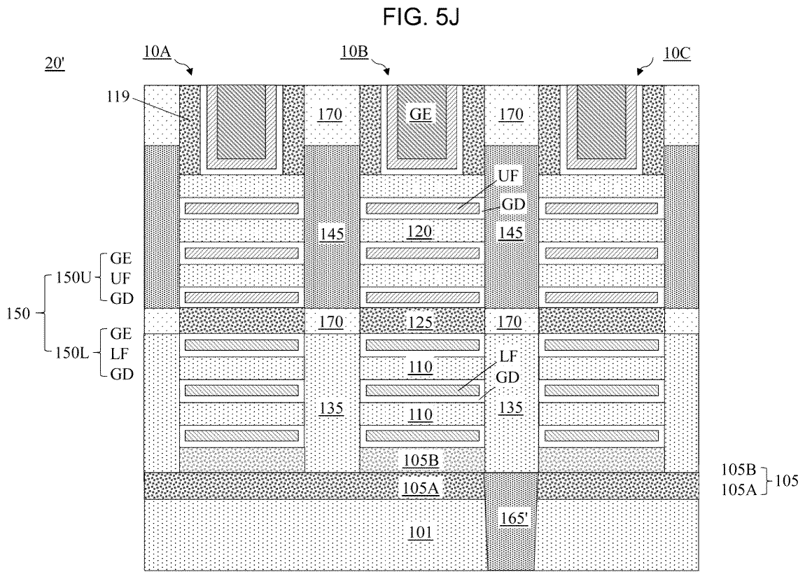

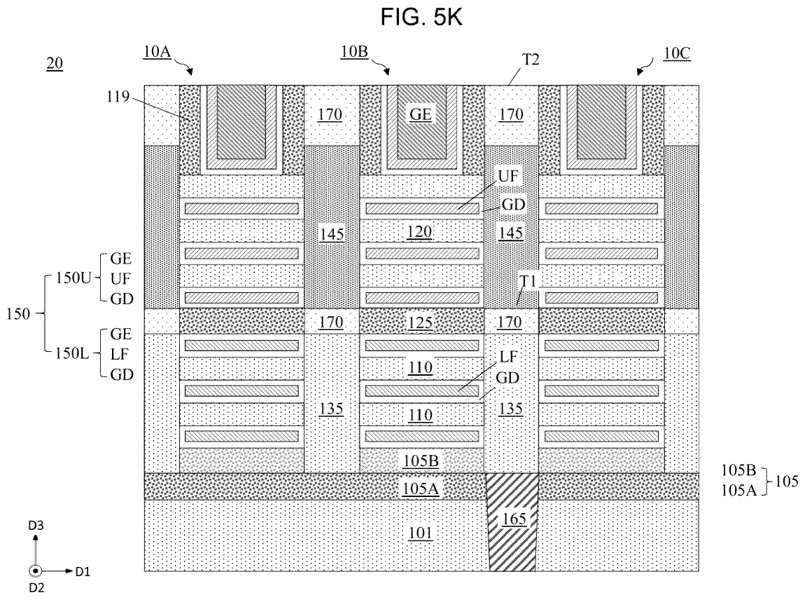

FIGS. 5A-5K illustrate cross-section views of intermediate semiconductor devices after respective steps of manufacturing a stacked semiconductor device in which a bottom isolation layer has different thicknesses below a gate structure and below a source/drain region, according to one or more embodiments.

The stacked semiconductor device manufactured through the steps described in reference to FIGS. 5A-5K may be or correspond to the stacked semiconductor device 20 shown in FIGS. 3A-3C. Thus, materials, functions, and structural characteristics of the intermediate semiconductor devices shown in FIGS. 5A-5K may be the same as or similar to those of the stacked semiconductor device 20 of FIGS. 3A-3C, and thus, duplicate descriptions may be omitted herein while the same reference characters or numerals used in reference to FIGS. 3A-3C may be used herebelow. It is also to be understood here that the cross-section views of FIGS. 5A-5K correspond to the cross-section view of the stacked semiconductor device 20 shown in FIG. 3A.

Referring to FIG. 5A, an initial channel stack may be formed by epitaxially growing a plurality of semiconductor layers one by one from a substrate 101. Further, a plurality of dummy gate structures 150′ may be formed on the initial channel stack to provide an intermediate semiconductor device 20′.

The initial channel stack formed on the substrate 101 may include a 1^{st} channel structure formed of 1^{st} sacrificial layers 108 and 1^{st} channel layers 110 vertically stacked in an alternating manner at a 1^{st} level and a 2^{nd} channel structure formed of 2^{nd} sacrificial layers 109 and 2^{nd} channel layers 120 vertically stacked in an alternating manner at a 2^{nd} level. Between the lowermost 1^{st} sacrificial layer 108 and the substrate 101 may be formed a bottom sacrificial layer including a 1^{st} bottom sacrificial layer 105A′ and a 2^{nd} bottom sacrificial layer 105B′. Further, a middle sacrificial layer 125′ may be formed between the uppermost 1^{st} sacrificial layer 108 and the lowermost 2^{nd} sacrificial layer 109.

While the substrate 101 and the channel layers 110 and 120 may be formed of silicon (Si), the sacrificial layers 105A , 105B′, 108, 125′ and 109 may be formed of silicon germanium (SiGe) with respective Ge concentrations therein. The 1^{st} bottom sacrificial layer 105A′ and the middle sacrificial layer 125′ may have a higher Ge concentration than the 2^{nd} bottom sacrificial layer 105B′, the 1^{st} sacrificial layers 108, and the 2^{nd} sacrificial layers 109. The 2^{nd} bottom sacrificial layer 105B′ may have a higher Ge concentration than the 1^{st} sacrificial layers 108 and the 2^{nd} sacrificial layers 109.

For example, the 1^{st} bottom sacrificial layer 105A′ and the middle sacrificial layer 125′ may have a Ge concentration of 45-50%, the 2^{nd} bottom sacrificial layer 105B′ may have a Ge concentration of 35-40%, and the 1^{st} sacrificial layers 108 and the 2^{nd} sacrificial layers 109 may have a Ge concentration of 25-30%.

The dummy gate structures 150′ may be formed on a top surface of the initial channel stack at positions below which respective channel stacks are to be formed in a later step (FIG. 5D). The dummy gate structures 150′ may be formed by depositing polysilicon (p-Si) or amorphous silicon (a-Si) on the initial channel stack through, for example, physical vapor deposition (PVD), chemical vapor deposition (CVD), plasma enhanced chemical vapor deposition (PECVD), or a combination thereof, to form an initial dummy gate structure, and applying photolithography/masking/etching on the initial dummy gate structure.

A purpose of forming the dummy gate structure 150′ is to protect structural elements formed therebelow from various operations such as deposition and etching performed to form surrounding structures in subsequent steps of manufacturing the stacked semiconductor device. The dummy gate structure 150′ may also serve to define dimensions of the channel layers 110 and 120 of each channel stack formed from the initial channel stack.

Referring to FIG. 5B, the 1^{st} bottom sacrificial layer 105A′ and the middle sacrificial layer 125′ may be removed from the initial channel stack to form respective voids.

The removal operation in this step may be performed through, for example, dry etching or wet etching using an etchant such as an ammonia-peroxide mixture which selectively removes the 1^{st} bottom sacrificial layer 105A′ and the middle sacrificial layer 125′ of SiGe with a higher Ge concentration while the 2^{nd} bottom sacrificial layer 105B′, the 1^{st} sacrificial layers 108, and the 2^{nd} sacrificial layers 109 with a lower Ge concentration are not or minimally attacked by the etchant.

Referring to FIG. 5C, an isolation layer 111 may be formed to surround the initial channel stack with the dummy gate structures 150′ thereon and fill in the two voids provided by the removal of the 1^{st} bottom sacrificial layer 105A′ and the middle sacrificial layer 125′ in the previous step (FIG. 5B).

The formation of the isolation layer 111 may be performed through, for example, depositing silicon nitride (e.g., SiN or Si₃N₄), SiBCN, SiCN, SiOC, SiOCN, or silicon oxide (e.g., SiO₂), not being limited thereto, on an outer surface of the intermediate semiconductor device 20′ and in the voids obtained in the previous step (FIG. 5B). The deposition used in this step may be atomic layer deposition (ALD), PVD, CVD, PECVD, plasma enhanced ALD (PEALD) or a combination thereof.

Thus, the two voids formed in the previous step may be filled in with the isolation layer 111, thereby forming a 1^{st} bottom isolation layer 105A and a middle isolation layer 125 respectively replacing the 1^{st} bottom sacrificial layer 105A′ and the middle sacrificial layer 125′. Further, the isolation layer 111 may be layered on top surfaces of the initial channel stack which includes top surfaces and side surfaces of the dummy gate structures 150′ and a top surface of the uppermost 2^{nd} channel layer 120 exposed between the dummy gate structures 150′.

Referring to FIG. 5D, the initial channel stack with the dummy gate structures 150′, the isolation layer 111, and a 2^{nd} bottom sacrificial layer 105B′ may be patterned based on portions of the isolation layer 111 formed on the top surfaces and the side surfaces of the dummy gate structures 150′ to obtain openings O1 and O2 where source/drain regions are to be formed, and the opening O2 is extended down into the substrate 101 through the 1^{st} bottom isolation layer 105A to form a recess R in the substrate 101 in which a placeholder structure for a backside contact structure is to be formed.

The patterning operation in this step may be performed through, for example, dry etching such as reactive ion etching based on the portions of the isolation layer 111 formed on the top surfaces and the side surfaces of the dummy gate structures 150′ and respective hard mask patterns formed thereon.

By the patterning operation in this step, a 1^{st} channel stack 10A, a 2^{nd} channel stack 10B and a 3^{rd} channel stack 10C may be formed with openings O1 and O2 therebetween. Each of the channel stacks 10A-10C may include a patterned 2^{nd} bottom sacrificial layer 105B′ on the 1^{st} bottom isolation layer 105A. Further, the patterning to form the opening O2 may vertically continue to form the recess R penetrating through the 1^{st} bottom isolation layer 105A into the substrate 101, while the opening O1 exposes a top surface of the 1^{st} bottom isolation layer 105A.

Thus, each of the channel stacks 10A-10C may include, on the 1^{st} bottom isolation layer 105A, a 2^{nd} bottom sacrificial layer 105B′, a 1^{st} channel structure including the 1^{st} sacrificial layers 108 and the 1^{st} channel layers 110, the middle isolation layer 125, a 2^{nd} channel structure including the 2^{nd} sacrificial layers 109 and the 2^{nd} channel layers 120, the dummy gate structure 150′ with the isolation layer 111 on a top surface and side surfaces thereof. Here, the isolation layer 111 on the top surface and the side surfaces of each of the dummy gate structure 150′ may form a gate spacer 119 of each of the channel stacks 10A-10C.

In each of the openings O1 and O2, side surfaces of the gate spacer 119, the channel layers 110, 120, the 2^{nd} bottom sacrificial layer 105B′ and the middle isolation layer 125 may be exposed and vertically aligned or coplanar.

Referring to FIG. 5E, the recess R in the substrate 101 may be filled in with a placeholder structure 165′ which reserves a space for a backside contact structure to be formed in a later step (FIG. 5K).

The placeholder structure 165′ may be formed of silicon germanium (SiGe) epitaxially grown from the substrate 101 through, for example, molecular beam epitaxy (MBE), vapor-phase epitaxy (VPE), etc., and processed or etched such that a top surface of the placeholder structure 165′ is horizontally coplanar or aligned with the top surface of the 1^{st} bottom isolation layer 105A or a bottom surface of the 2^{nd} bottom sacrificial layer 105B'.

Alternatively, the placeholder structure 165′ may be formed such that the top surface thereof is at a level below or above the bottom surface of the 2^{nd} bottom sacrificial layer 105B′ but below a bottom surface of the gate structure 150.

Referring to FIGS. 5F, 1^{st} source/drain regions 135 and 2^{nd} source/drain regions 145 may be formed in the openings O1 and O2 based on the 1^{st} channel layers 110 and the 2^{nd} channel layers 120, respectively.

The 1^{st} source/drain regions 135 may be epitaxially grown in the openings O1 and O2 based on the 1^{st} channel layers 110 through, for example, MBE, VPE, etc., not being limited thereto. As the lowermost 1^{st} channel layer is vertically above the 2^{nd} bottom sacrificial layer 105B′ and the lowermost 1^{st} sacrificial layer 108, the 1^{st} source/drain region 135 may be grown to have a greater volume at least by a thickness of the 2^{nd} bottom sacrificial layer 105B′ compared to the 1^{st} source/drain region 135 in the stacked semiconductor device 10 shown in FIGS. 2A-2C. A bottom surface of the 1^{st} source/drain region 135 may directly contact the top surface of the placeholder structure 165′. As the 1^{st} source/drain region 135 is formed in the above manner, the 1^{st} source/drain region 135 may contact the side surfaces of the 2^{nd} bottom sacrificial layers 105B′ and the 1^{st} sacrificial layers 108 as well as the 1^{st} channel layers 110 in the openings O1 and O2.

The 1^{st} source/drain regions 135 may be formed of silicon (Si) and may be doped in-situ with impurities such as phosphorus (P), arsenic (As), antimony (Sb), etc., so that the 1 st source/drain region 135 can be of an n-type. Alternatively, the 1^{st} source/drain regions 135 may be formed of silicon germanium (SiGe) and may be doped in-situ with impurities such as boron (B), gallium (Ga), indium (In), etc., so that the 1^{st} source/drain regions 135 can be of a p-type.

After formation of the 1^{st} source/drain regions 135, an interlayer isolation structure 170 may be formed above the 1^{st} source/drain regions 135 to isolate the 1^{st} source/drain regions 135 from other circuit elements. The interlayer isolation structure 170 may be formed of a low-k dielectric material such as silicon oxide (e.g., SiO₂).

The 2^{nd} source/drain regions 145 may be epitaxially grown from the 2^{nd} channel layers 120 through, for example, MBE, VPE, etc., not being limited thereto. The 2^{nd} source/drain regions 145 may be formed of silicon (Si) and may be doped in-situ with impurities such as P, As, Sb, etc., so that the 2^{nd} source/drain regions 145 can be of an n-type. Alternatively, the 2^{nd} source/drain regions 145 may be formed of SiGe and may be doped in-situ with impurities such as B, Ga, In, etc., so that the 2^{nd} source/drain regions 145 can be of a p-type.

After forming the 2^{nd} source/drain regions 145, an additional interlayer isolation structure 170 may be formed on the 2^{nd} source/drain regions 145.

Referring to FIG. 5G, the 2^{nd} bottom sacrificial layer 105B′ and the dummy gate structure 150′ may be removed from each of the channel stacks 10A-10C.

The 2^{nd} bottom sacrificial layer 105B′ and the dummy gate structure 150′ may be removed to provide respective spaces for a 2^{nd} bottom isolation layer and a gate structure in each of the channel stacks 10A-10C in later steps (FIGS. 5J and 5H). Prior to removing each of the dummy gate structures 150′, a portion of the gate spacer 119 formed on the top surface of each of the dummy gate structures 150′ may be first removed by dry etching or wet etching to expose the dummy gate structure 150′.

The removal of the dummy gate structures 150′ and the 2^{nd} bottom sacrificial layer 105B′ may be performed through, for example, dry etching, wet etching, or a combination thereof, not being limited thereto, using an etchant such as ammonia peroxide, nitric acid (HNO₃) and hydrofluoric acid (HF), and/or a combination thereof, not being limited thereto. In this step, due to the difference of the Ge concentration in the SiGe sacrificial layers, that is, the 2^{nd} bottom sacrificial layer 105B′ and the 1^{st} and 2^{nd} sacrificial layers 108 and 109, only the 2^{nd} bottom sacrificial layer 105B′ with a higher Ge concentration may be selectively removed while the 1^{st} sacrificial layers 108 and the 2^{nd} sacrificial layers 109 with a lower Ge concentration are not or minimally attacked by the etchant.

Referring to FIG. 5H, a space provided by the removal of the 2^{nd} bottom sacrificial layer 105B′ may be filled in with a 2^{nd} bottom isolation layer 105B.

The 2^{nd} bottom isolation layer 105B replacing the 2^{nd} bottom sacrificial layer 105B′ may include an isolation material such as silicon nitride (e.g., SiN or Si₃N₄), SiBCN, SiCN, SiOC, SiOCN, or silicon oxide (e.g., SiO₂), not being limited thereto, which may be the same as or different from the material or materials forming the 1^{st} bottom isolation layer 105A and the middle isolation layer 125. Even when the two bottom isolation layers 105A and 105B are formed to have the same material composition, a junction or interface between the two layers may be formed because the two layers are formed at different steps. When the two bottom isolation layers 105A and 105B are formed to have different material compositions, different isolation characteristics may be achieved.

The formation of the 2^{nd} bottom isolation layer 105B may be performed through, for example, ALD, PEALD, PECVD, etc., not being limited thereto.

Referring to FIG. 5I, the 1^{st} sacrificial layers 108 and the 2^{nd} sacrificial layers 109 of SiGe with a low Ge concentration may be removed through, for example, dry etching, wet etching, or a combination thereof, not being limited thereto, using an etchant such as, for example, a mixture of HNO₃ and HF, not being limited thereto.

Referring to FIG. 5J, the spaces formed by the removal of the dummy gate structures 150′, the 1^{st} sacrificial layers 108 and the 2^{nd} sacrificial layers 109 may be filled in with the gate structure 150.

A gate dielectric layer GD may be first formed on the 1^{st} channel layers 110 and the 2^{nd} channel layers 120 in the space formed by the removal of the 1^{st} sacrificial layers 108 and the 2^{nd} sacrificial layers 109, followed by formation of a 1^{st} work-function metal layer LF and a 2^{nd} work-function metal layer UF, respectively, and then formation of a gate electrode GE.

The gate dielectric layer GD may include an interfacial layer which may be formed on an outer surface of each of the channel layers 110 and 120 through, for example, thermal oxidation or annealing of the channel layers 110 and 120. After the interfacial layer is formed on the channel layers 110 and 120, a high-k dielectric layer may be formed through, for example, CVD, ALD, PEALD, etc. or a combination thereof, not being limited thereto, on the interfacial layer. The interfacial layer may be formed of an oxide material such as silicon oxide (SiO or SiO₂) and/or silicon oxynitride (SiON), not being limited thereto, and the high-k dielectric layer may include a high-k material such as hafnium oxide (HfO₂), hafnium silicate (HfSiO₄), titanium oxide (TiO₂), zirconium oxide (ZrO₂), aluminum oxide (Al₂O₃), lanthanum oxide (La₂O₃), yttrium oxide (Y₂O₃), etc. The gate dielectric layer GD may isolate the work-function metal layers LF and UF from the source/drain regions 135 and 145, respectively.

The work-function metal layers LF and UF may be formed to surround the gate dielectric layer on the channel layers 110 and 120, respectively, through, for example, CVD, ALD, PECVD, PEALD, or a combination thereof of a metal such as Ti, Ta, Al, W, TiN, WN, TiAl, TiAlN, TaN, TiC, TaC, TiAlC, TaCN, TaSiN, and/or a combination thereof, not being limited thereto. The gate electrode GE may be formed on the work-function metal layers LF and UF through, for example, CVD, PVD, PECVD, etc., or a combination thereof of a metal such as Cu, W, Al, Ru, Mo, Co, etc., or a metal alloy thereof.

Referring to FIG. 5K, a backside process may be performed on the intermediate semiconductor device 20′ obtained in the previous step (FIG. 5J) to form a backside contact structure 165 connected to a bottom surface of the 1^{st} source/drain region 135, thereby forming a stacked semiconductor device with a bottom isolation layer having different thicknesses.

The backside process in this step may be performed by flipping upside down the intermediate semiconductor device 20′ of FIG. 5J, removing the placeholder structure 165′ and filling a space provided by the removal of the placeholder structure 165′ with a backside contact structure 165 formed of a metal or a metal alloy. Thus, a top surface of the backside contact structure 165 may contact the bottom surface of the 1^{st} source/drain region 135. When silicidation is performed on the top surface of the backside contact structure 165 or the bottom surface of the 1^{st} source/drain region 135 to improve connection performance, the top surface of the backside contact structure 165 may contact the bottom surface of the 1^{st} source/drain region 135 though a silicide layer therebetween.

The removal of the placeholder structure 165′ of SiGe may be performed through, for example, dry etching or wet etching using an etchant such as hydrofluoric acid (HF), not being limited thereto, and the formation of the backside contact structure 165 may be performed through, for example, PVD, CVD, PECVD, etc. or a combination thereof, not being limited thereto.

Alternatively, for the backside process, at least a portion of the substrate 101 may be removed or replaced by a backside isolation structure formed of a low-k material such as silicon oxide (e.g., SiO₂), and then, the backside isolation structure may be patterned to expose the placeholder structure 165′ prior to the replacement of the placeholder structure 165′ by the backside contact structure 165.

The above-described embodiments are directed to a stacked semiconductor device in which two bottom isolation layers, for example, the 1^{st} bottom isolation layer 105A and the 2^{nd} bottom isolation layer 105B, are formed to increase a distance between the gate structure 150 and the backside contact structure 165 and increase a volume of the 1^{st} source/drain region 135. However, the disclosure is not limited thereto. According to one or more other embodiments, three or more bottom isolation layers may be formed vertically below the gate structure so that a sum thickness of the bottom isolation layers may be greater than that below the 1^{st} source/drain region.

The above-described embodiments are directed to a stacked semiconductor device in which each of two stacked transistors is a nanosheet transistor. However, the disclosure is not limited thereto. According to one or more other embodiments, each of the two stacked transistors may be a different type of field-effect transistor such as FinFET or forksheet transistor.

In the above-described embodiments, the bottom isolation layer having different thicknesses below a gate structure and below a source/drain region is formed in a stacked semiconductor device. However, the disclosure is not limited thereto. According to one or more other embodiments, the same bottom isolation layer may be formed in a single-stack semiconductor device in which only the 1^{st} channel structure, the 1^{st} source/drain regions 135 and the 1^{st} gate structure 150L is formed.

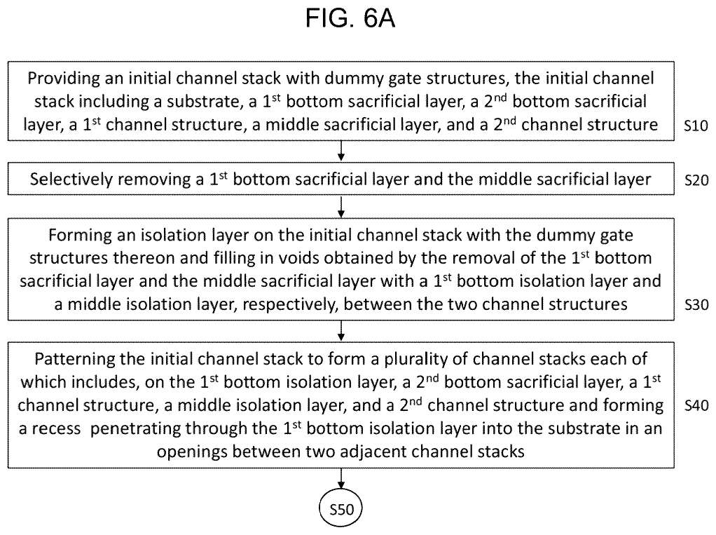

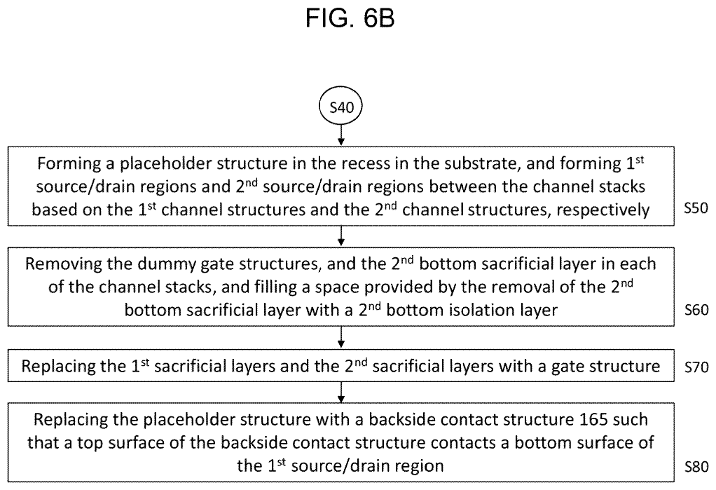

FIGS. 6A and 6B illustrate a flowchart of a method of manufacturing a stacked semiconductor device in which a bottom isolation layer has different thicknesses below a gate structure and below a source/drain region, according to one or more other embodiments.

The semiconductor device manufactured according to the flowchart of FIGS. 6A and 6B may be the same as or correspond to the stacked semiconductor device 20 shown in FIGS. 3A-3C, and operations performed for each step of manufacturing the stacked semiconductor device may be the same as or similar to those described above in reference to FIGS. 5A-5K. Thus, duplicate descriptions may be omitted herein.

In step S10, an initial channel stack with a plurality of dummy gate structures thereon is provided. The initial channel stack may include, on a substrate, a 1^{st} bottom sacrificial layer, a 2^{nd} bottom sacrificial layer, a 1^{st} channel structure, a middle sacrificial layer, and a 2^{nd} channel structure vertically stacked in this order.

The 1^{st} channel structure may include 1^{st} sacrificial layers and 1^{st} channel layers alternatingly stacked in a vertical direction, and the 2^{nd} channel structure may include 2^{nd} sacrificial layers and 2^{nd} channel layers also alternatingly stacked in the vertical direction. The channel layers included in the two channel structures may be formed of silicon (Si) while the 1^{st} bottom sacrificial layer, the 2^{nd} bottom sacrificial layer, the middle sacrificial layer, and the 1^{st} and 2^{nd} sacrificial layers may all be formed of silicon germanium (SiGe). However, the 1^{st} sacrificial layer and the middle sacrificial layer may have a same higher Ge concentration, e.g., 45-50%, than the other sacrificial layers, and the 2^{nd} bottom sacrificial layer may have a higher Ge concentration, e.g., 35-40%, than the 1^{st} and 2^{nd} sacrificial layers of, e.g., 25-30%.

In step S20, the 1^{st} bottom sacrificial layer and the middle sacrificial layer may be removed through, for example, dry etching or wet etching using an etchant selectively removing these two sacrificial layers of the highest Ge concentration against the rest of the sacrificial layers with a low Ge concentration and the channel layers of Si.

In step S30, an isolation layer may be formed along an outer profile of the initial channel stack with the dummy gate structures thereon, and may fill in voids obtained by the removal of the 1^{st} bottom sacrificial layer and the middle sacrificial layer with a 1^{st} bottom isolation layer and a middle isolation layer, respectively, and may form gate spacers on each of the dummy gate structures.

Here, a portion of the isolation layer filled in the voids may form the 1^{st} bottom isolation layer and the middle isolation layer, and portions of the isolation layer on side surfaces and a top surface of each dummy gate structure may form the gate spacers. The isolation layer formed in this step may be silicon nitride (e.g., SiN or Si₃N₄), SiBCN, SiCN, SiOC, SiOCN, silicon oxide (e.g., SiO₂), etc., not being limited thereto.

In step S40, the initial channel stack may be patterned based on the dummy gate structures with the isolation layer thereon to form a plurality of channel stacks with openings therebetween so that each of the channel stacks includes, on the 1^{st} bottom isolation layer, a 2^{nd} bottom sacrificial layer, a 1^{st} channel structure, a middle isolation layer, and a 2^{nd} channel structure below a dummy gate structure with the gate spacer thereon.

As the initial channel stack is patterned, an opening may be formed between two adjacent channel stacks to expose side surfaces of the channel layers and the sacrificial layers as well as the middle isolation layer and the 2^{nd} bottom sacrificial layer. Further, a recess may be formed through one of the openings penetrating through the 1^{st} bottom isolation layer into the substrate.

In step S50, a placeholder structure may be formed in the recess in the substrate, and 1^{st} source/drain regions and 2^{nd} source/drain regions may be formed in the openings obtained in the previous step based on the 1^{st} channel structures and the 2^{nd} channel structures, respectively, of the channel stacks. Further, an interlayer isolation structure may be formed to surround the 1^{st} source/drain regions and the 2^{nd} source/drain regions.

The placeholder structure may be formed of silicon germanium (SiGe) epitaxially grown from the substrate in the recess. The 1^{st} source/drain regions and the 2^{nd} source/drain regions may be epitaxially grown from the channel layers exposed to the openings above the placeholder structure.

As the lowermost 1^{st} channel layer of the 1^{st} channel structure is vertically above the 2^{nd} bottom sacrificial layer and the lowermost 1^{st} sacrificial layer, the 1^{st} source/drain region grown from the 1^{st} channel layers may be formed to contact side surfaces of the 2^{nd} bottom sacrificial layer and the lowermost 1^{st} sacrificial layer and the top surface of the placeholder structure.

In step S60, the dummy gate structure and the 2^{nd} bottom sacrificial layer in each of the channel stacks may be removed, and a space provided by the removal of the 2^{nd} bottom sacrificial layer may be filled in with a 2^{nd} bottom isolation layer formed of an isolation material which may be the same or different from the material forming the 1^{st} bottom isolation layer.

In step S70, the 1^{st} sacrificial layers and the 2^{nd} sacrificial layers in each of the channel stacks may be removed, and replaced by a gate structure.

The gate structure may include a gate dielectric layer on each of the channel layers in the two channel structures, a 1^{st} work-function metal layer replacing the 1^{st} sacrificial layers and surrounding the gate dielectric layer on the 1^{st} channel layers, a 2^{nd} work-function metal layer replacing the 2^{nd} sacrificial layers and surrounding the gate dielectric layer on the 2^{nd} channel layers, and a gate electrode surrounding the work-function metal layers.

In step S80, the placeholder structure may be removed and replaced by a backside contact structure such that a top surface of the backside contact structure may contact the bottom surface of the 1^{st} source/drain region with or without a silicide layer therebetween.

Through the above-described steps, a stacked semiconductor device may be manufactured to include two bottom isolation layer between the gate structure and the substrate while only one bottom isolation layer is formed between the 1^{st} source/drain region and the substrate.

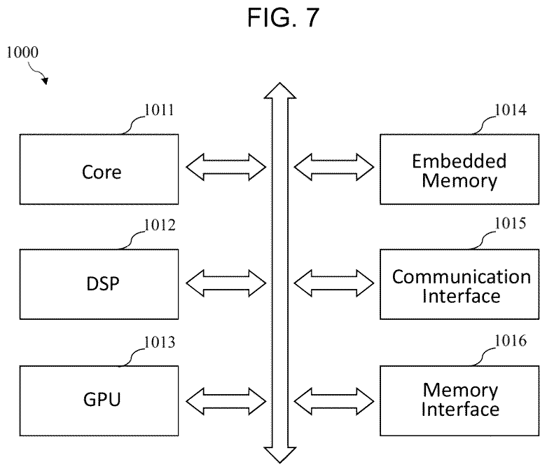

FIG. 7 is a schematic block diagram illustrating an electronic device including a stacked semiconductor device in which a bottom isolation layer has different thicknesses below a gate structure and below a source/drain region, according to one or more embodiments. This stacked semiconductor device included in the electronic device may be or correspond to the stacked semiconductor device 20, 30A, 30B or 30C shown in FIGS. 3A-3C and 4A-4C.

Referring to FIG. 7, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (RAM) (DRAM), a flash memory, etc.

At least one of the core 1011, the DSP 1012, the GPU 1013, and/or the embedded memory 1014 may include the stacked semiconductor device 20, 30A, 30B or 30C shown in FIGS. 3A-3C and 4A-4C.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a channel structure;
a 1^{st} source/drain region on the channel structure;
a gate structure on the channel structure; and
a bottom isolation layer below the gate structure and the 1^{st} source/drain region,
wherein the bottom isolation layer is thicker vertically below the gate structure than vertically below the 1^{st} source/drain region.

2. The semiconductor device of claim 1, wherein a bottom surface and a lower side surface of the 1^{st} source/drain region contacts the bottom isolation layer.

3. The semiconductor device of claim 1, wherein the bottom isolation layer comprises a 1^{st} bottom isolation layer and a 2^{nd} bottom isolation layer vertically above the 1^{st} bottom isolation layer, and
wherein a bottom surface of the 1^{st} source/drain region contacts a top surface of the 1^{st} bottom isolation layer, and a lower side surface of 1^{st} source/drain region contacts a side surface of the 2^{nd} bottom isolation layer.

4. The semiconductor device of claim 1, wherein the bottom isolation layer vertically below the gate structure comprises a 1^{st} bottom isolation layer and a 2^{nd} bottom isolation layer vertically above the 1^{st} bottom isolation layer, and
wherein the bottom isolation layer vertically below the 1^{st} source/drain region comprises only the 1^{st} bottom isolation layer among the 1^{st} bottom isolation layer and the 2^{nd} bottom isolation layer.

5. The stacked semiconductor device of claim 4, wherein a bottom surface of the 1^{st} source/drain region contacts a top surface of the 1^{st} bottom isolation layer, and a lower side surface of the 1^{st} source/drain region contacts a side surface of the 2^{nd} bottom isolation layer.

6. The semiconductor device of claim 1, further comprising:
a 2^{nd} source/drain region connected to the 1^{st} source/drain region through the channel structure; and
a backside contact structure connected to the 2^{nd} source/drain region,
wherein the backside contact structure penetrates through the 1^{st} bottom isolation layer to be connected to the 2^{nd} source/drain region.

7. The semiconductor device of claim 6, wherein a top surface of the backside contact structure is at a level below a bottom surface of the gate structure.

8. The semiconductor device of claim 6, wherein the bottom isolation layer comprises a 1^{st} bottom isolation layer and a 2^{nd} bottom isolation layer vertically above the 1 st bottom isolation layer,
wherein a top surface of the backside contact structure is at a substantially same level as a top surface of the 1^{st} bottom isolation layer.

9. The semiconductor device of claim 1, wherein the bottom isolation layer comprises a 1^{st} bottom isolation layer and a 2^{nd} bottom isolation layer vertically above the 1 st bottom isolation layer, vertically below the gate structure, and
wherein the 1^{st} bottom isolation layer and the 2^{nd} bottom isolation layer have a same material composition.

10. The semiconductor device of claim 9, wherein a top surface of the 1^{st} bottom isolation layer contacts a bottom surface of the 2^{nd} bottom isolation layer.

11. The semiconductor device of claim 1, wherein the bottom isolation layer comprises a 1^{st} bottom isolation layer and a 2^{nd} bottom isolation layer vertically above the 1 st bottom isolation layer, vertically below the gate structure, and
wherein the 1^{st} bottom isolation layer and the 2^{nd} bottom isolation layer have different material compositions.

12. A semiconductor device comprising:
a base layer comprising silicon or a dielectric material;
a channel structure on the base layer;
a 1^{st} source/drain region on the channel structure;
a gate structure on the channel structure; and
a bottom isolation layer having different thicknesses along a channel-length direction on the base layer and vertically below the channel structure, the gate structure and the 1^{st} source/drain region.

13. The semiconductor device of claim 12, wherein the bottom isolation layer is thicker vertically below the gate structure than vertically below the 1^{st} source/drain region.

14. The semiconductor device of claim 12, wherein the bottom isolation layer comprises a greater number of isolation layers vertically below the gate structure than vertically below the 1^{st} source/drain region.

15. The semiconductor device of claim 12, further comprising:
a 2^{nd} source/drain region connected to the 1^{st} source/drain region through the channel structure; and
a backside contact structure connected to the 2^{nd} source/drain region through the base layer and the bottom isolation layer.

16. The semiconductor device of claim 15, wherein a top surface of the backside contact structure vertically below the 2^{nd} source/drain region is at a substantially same level as a top surface of the bottom isolation layer vertically below the 1^{st} source/drain pattern.

17. The semiconductor device of claim 12, wherein a bottom surface and a side surface of the 1^{st} source/drain region contacts the bottom isolation layer.

18. A method of manufacturing a semiconductor device, the method comprising:
forming a base layer;
forming a channel structure on the base layer;
forming a 1^{st} source/drain region on the channel structure;
forming a gate structure on the channel structure; and
forming a bottom isolation layer having different thicknesses along a channel-length direction on the base layer below the channel structure, the gate structure and the 1^{st} source/drain region.

19. The method of claim 18, wherein the bottom isolation layer is formed such that a portion vertically below the gate structure has a greater thickness than a portion vertically below the 1^{st} source/drain region.

20. The method of claim 18, wherein the bottom isolation layer is formed to comprise a greater number of isolation layers vertically below the gate structure than vertically below the 1^{st} source/drain region.
